(19) United States
(12) Patent Application Publication
(10) Pub. No.: US 2020/0098835 A1
(43) Pub. Date: Mar. 26, 2020

(54) ELECTRONIC DEVICE FOR IMPROVING PHENOMENON OF VISUAL RECOGNITION IN PARTIAL AREA OF DISPLAY

(71) Applicant: Samsung Electronics Co., Ltd., Suwon-si (KR)

(72) Inventors: Jongkon BAE, Suwon-si (KR); Hanyuool KIM, Suwon-si (KR); Byungduk YANG, Suwon-si (KR); Dongkyoon HAN, Suwon-si (KR)

(21) Appl. No.: 16/575,676

(22) Filed: Sep. 19, 2019

(30) Foreign Application Priority Data
Sep. 21, 2018 (KR) 10-2018-0113900

(51) Int. Cl. H01L 27/32; G06F 1/16; G09G 3/20; G09G 3/36

(52) U.S. Cl. CPC H01L 27/3218; H01L 27/3216; G09G 2360/144; G09G 3/2074; G09G 3/3607; G06F 1/1637

(57) ABSTRACT

An electronic device is provided. The electronic device includes a housing, a display at least partially disposed inside the housing, and a sensor. The display includes a display panel, first-type pixels disposed on a first area, which corresponds to the sensor, of the display panel, and second-type pixels disposed on a second area of the display panel other than the first area. Each of the first-type pixels includes a first-red-subpixel, a first-blue-subpixel, and a first-green-subpixel, each of the second-type pixels includes a second-red-subpixel smaller than the first-red-subpixel, a second-blue-subpixel smaller than the first-blue-subpixel, and a second-green-subpixel smaller than the first-green subpixel. A first arrangement in which the first-red-subpixel, the first-blue-subpixel, and the first-green-subpixel are arranged is different from a second arrangement in which the second-red-subpixel, the second-blue-subpixel, and the second-green-subpixel are arranged.

### CROSS-REFERENCE TO RELATED APPLICATION(S)

This application is based on and claims priority under 35 U.S.C. § 119(a) of a Korean patent application number 10-2018-0113900, filed on Sep. 21, 2018, in the Korean Intellectual Property Office, the disclosure of which is incorporated by reference herein its entirety.

### BACKGROUND

### 1. Field

The disclosure relates to a technology of improving a phenomenon that a partial area of the display is visually recognized.

### 2. Description of Related Art

Currently, as the demand of a consumer for a larger screen is increasing, a technology associated with a full front display has been actively developed. When the full front display is mounted on an electronic device (e.g., a smart phone) and a user views the electronic device from the front, the full front display may occupy a large part of the front surface of the electronic device.

Meanwhile, various sensors, such as a camera, an illumination sensor, or a proximity sensor may be mounted in the electronic device. The sensors are disposed on a rear surface of the full front display, so the sensors may receive light through openings formed in the full front display. For example, a smaller number of pixels may be present in an area, which corresponds to the sensors, of the full front display as compared to the remaining area of the full front display. The sensors may capture a picture or measure illuminance by receiving light through the area in which a smaller number of pixels are disposed.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device capable of improving a phenomenon that a partial area of the display is visually recognized.

In the full front display, the area, in which a smaller number of pixels are disposed, and the remaining area may be different from each other as to brightness. For example, the area in which a smaller number of pixels are disposed may be displayed more darkly as compared to the remaining area or in black. Accordingly, the user may recognize the area in which a smaller number of pixels are disposed and may feel the sense of difference due to the area being visually distinct.

Additional aspects will be set forth in part in the description which follows and, in part, will be apparent from the description, or may be learned by practice of the presented embodiments.

In accordance with an aspect of the disclosure, an electronic device is provided. The electronic device includes a housing, a display at least partially disposed inside the housing, and, a sensor. The display may include a display panel, first-type pixels disposed on a first area, which corresponds to the sensor, of the display panel, and second-type pixels disposed on a second area of the display panel other than the first area. Each of the first-type pixels may include a first-red-subpixel, a first-blue-subpixel, and a first-green-subpixel, and each of the second-type pixels may include a second-red-subpixel smaller than the first-red-subpixel, a second-blue-subpixel smaller than the first-blue-subpixel, and a second-green-subpixel smaller than the first-green subpixel. A first arrangement in which the first-red-subpixel, the first-blue-subpixel, and the first-green-subpixel are arranged may be different from a second arrangement in which the second-red-subpixel, the second-blue-subpixel, and the second-green-subpixel are arranged.

In accordance with another aspect of the disclosure, a display is provided. The display includes a display panel, first-type pixels disposed on a first area, which corresponds to an external sensor, of the display panel, and second-type pixels disposed on a second area of the display panel other than the first area. Each of the first-type pixels may include a first-red-subpixel, a first-blue-subpixel, and a first-green-subpixel, and each of the second-type pixels may include a second-red-subpixel smaller than the first-red-subpixel, a second-blue-subpixel smaller than the first-blue-subpixel, and a second-green-subpixel smaller than the first-green subpixel. A first arrangement in which the first-red-subpixel, the first-blue-subpixel, and the first-green-subpixel are arranged may be different from a second arrangement in which the second-red-subpixel, the second-blue-subpixel, and the second-green-subpixel are arranged.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates an electronic device according to a comparative example and a second electronic device, according to an embodiment of the disclosure;

FIG. 2 is a cross-sectional view illustrating an electronic device, according to an embodiment of the disclosure;

FIG. 3 is an enlarged view of a partial area of a display, according to an embodiment of the disclosure;

FIG. 4 is an enlarged view of a partial area of a display, according to an embodiment of the disclosure;

FIG. 5 is an enlarged view illustrating a partial area of a display, according to an embodiment of the disclosure;

FIG. 6 is a block diagram illustrating an electronic device in a network environment according to an embodiment of the disclosure; and

FIG. 7 is a block diagram illustrating a display device according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

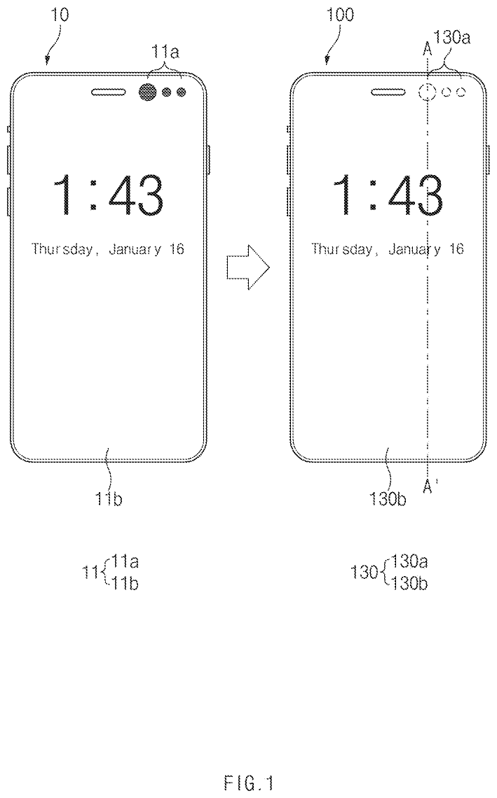

FIG. 1 illustrates an electronic device according to a comparative example and an electronic device according to an embodiment of the disclosure. FIG. 1 illustrates an electronic device 10 according to a comparative example, and an electronic device 100 according to an embodiment of the disclosure.

Referring to FIG. 1, the electronic device 10 according to a comparative example may include a display 11 and a sensor (e.g., a camera, or a proximity sensor).

The display 11 may be disposed inside the electronic device 10 according to the comparative example. The display 11 may occupy the most part of the front surface of the electronic device 10 according to the comparative example when viewed from the front surface of the electronic device 10.

The sensor may be disposed on the rear surface of the display 11. As the sensor is disposed on the rear surface of the display 11, the sensor may not be exposed out of the electronic device 10 according to a comparative example. According to a comparative example, the sensor may receive light through an opening formed in the display 11. For example, the number of pixels (or resolution), which are disposed in an area 11a of the display 11 corresponding to the sensor, per unit area may be smaller than the number of pixels (or resolution), which are arranged in the remaining area 11b, per unit area. The sensor may capture a picture or may measure the distance from an external object by receiving the light through the area 11a in which a smaller number of pixels are arranged.

According to the electronic device 10 of the comparative example, the area 11a, in which the smaller number of pixels are disposed, of the display 11 may be different from the remaining area 11b in brightness. For example, the area 11a in which a smaller number of pixels are disposed may be displayed more darkly than the remaining area 11b or in black. Accordingly, the user may recognize the area 11a in which a smaller number of pixels are disposed.

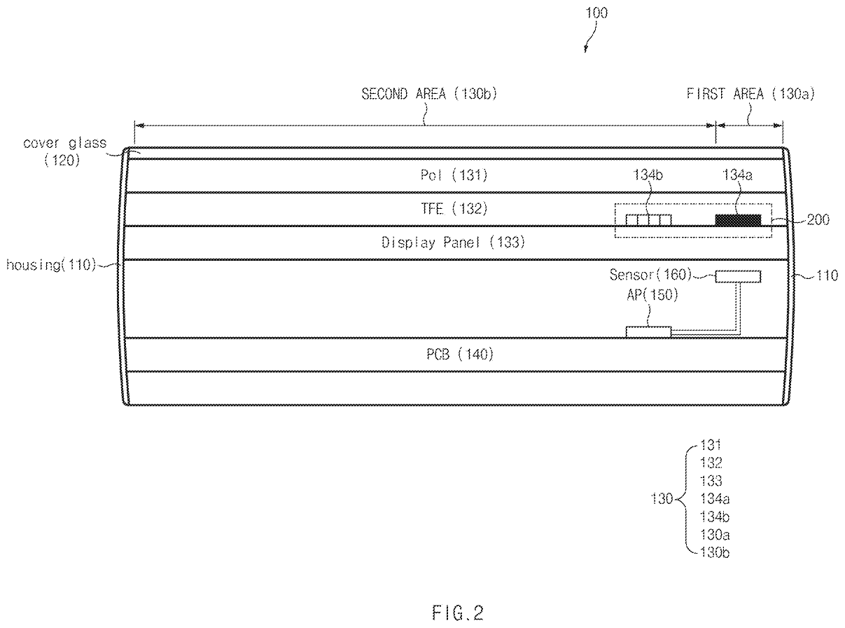

According to an embodiment of the disclosure, an electronic device 100 may include a display 130 and a sensor (e.g., 160 of FIG. 2; a camera, a proximity sensor, an illumination sensor, a biometrics sensor, a fingerprint sensor, or an infrared (IR) sensor).

The display 130 may be disposed inside the electronic device 100 and the sensor 160 may be disposed on the rear surface of the display 130. The sensor 160 may be disposed on the rear surface of the display 130, so the sensor 160 may not be exposed out of the electronic device 100.

According to an embodiment of the disclosure, the sensor 160 may receive light through an opening formed in the display 130. For example, the opening may be formed in an area (hereinafter, referred to as a “first area 130a”), which corresponds to the sensor 160, of the display 130. The sensor 160 may obtain image information (e.g., may capture a picture) or sense an external object (e.g., may measure the distance from the external object) by receiving the light through the opening.

According to an embodiment of the disclosure, the first area 130a and a remaining area (hereinafter, referred to as a “second area 130b”) are visually identically recognized in brightness by a user, so the first area 130a and the second area 130b may not be visually distinguished therebetween. For example, the size of pixels disposed in the first area 130a may be larger than the size of pixels disposed in the second area 130b. The size of pixels disposed in the first area 130a may be larger than the size of pixels disposed in the second area 130b, so the first area 130a and the second area 130b may be substantially similar to each other in brightness even if a smaller number of pixels are disposed in the first area 130a. The first area 130a and the second area 130b are substantially similar to each other in brightness, so the user may not recognize that the first area 130a is visually different from the second area 130b (e.g., may recognize that the first area 130a is visually similar to the second area 130b).

According to another embodiment of the disclosure, the brightness of pixels arranged in the first area 130a may be brighter than the brightness of pixels arranged in the second area 130b. Accordingly, even if a smaller number of pixels are arranged in the first area 130a, the brightness of the first area 130a may be substantially similar to the brightness of the second area 130b. The first area 130a and the second area 130b are substantially similar to each other in brightness, so the user may not recognize that the first area 130a is visually different from the second area 130b (e.g., may recognize that the first area 130a is visually similar to the second area 130b).

FIG. 2 is a cross-sectional view illustrating an electronic device according to an embodiment of the disclosure. FIG. 2 illustrates a cross-sectional view taken along line A-A′ of the electronic device 100 illustrated in FIG. 1.

Referring to FIG. 2, the electronic device 100 may include a housing 110, a cover glass 120, the display 130, a printed circuit board 140, a processor 150, and the sensor 160.

The housing 110 may form an outer appearance of a side surface of the electronic device 100. In addition, the housing 110 may protect components included in the electronic device 100. For example, the display 130 and the printed circuit board 140 may be mounted inside the housing 110, and the housing 110 may protect the components from an external impact.

The cover glass 120 may transmit light generated by the display 130. In addition, as the user touches the cover glass 120 with a part of the physical body (e.g., a finger) of the user, a touch operation (including the contact with an electronic pen) is performed. The cover glass 120 may include, for example, a tampered glass, reinforced plastic, or a flexible polymeric material. According to an embodiment, the cover glass 120 may be referred to as a “glass window”.

The printed circuit board 140 may allow the mounting of various electronic parts, a device, and a printed circuit of the electronic device 100. The printed circuit board 140 may allow the mounting of an application processor (AP), a communication processor (CP) or a memory. In the disclosure, the printed circuit board 140 may be referred to as a printed circuit board (PCB), a main board, or a printed board assembly (PBA).

The processor 150 (e.g., AP) may be disposed on the printed circuit board 140. The processor 150 may be electrically connected with parts (e.g., the display 130) included in the electronic device 100.

The sensor 160 may be electrically connected with the processor 150 through specified wirings (e.g., flexible printed circuit board (FPCB)). The sensor 160 may capture a picture, may calculate the distance from an external object, or may measure illuminance, through the first area 130a. In the disclosure, the sensor 160 may be referred to as a camera, an illumination sensor, or a proximity sensor.

The display 130 may include a polarizer 131, an encapsulation layer 132, a substrate 133 (i.e., display panel), first-type pixels 134a, or second-type pixels 134b.

The polarizer 131 (or polarizing film) may transmit only light, which oscillates in any one direction, of light input through the cover glass 120. For example, the polarizer 131 may transmit only light vertically oscillating and may block light horizontally oscillating.

The encapsulation layer 132 may be interposed between the polarizer 131 and the substrate 133. The encapsulation layer 132 may protect pixels 134a and 134b disposed on the substrate 133. In the disclosure, the encapsulation layer 132 may be referred to as a thin film encapsulation (TFE) or encapsulation glass.

A plurality of wirings and the pixels 134a and 134b may be disposed on the substrate 133. For example, a plurality of gate lines and a plurality of data lines may be arranged on the substrate 133 and may cross each other. The pixels 134a and 134b may emit light based on signals supplied from the gate lines and the data lines. In the disclosure, the substrate 133 may be referred to as a display panel.

According to an embodiment, the substrate 133 may include the first area 130a and the second area 130b. The first area 130a may refer to an area, which corresponds to the sensor 160, of the substrate 133. The second area 130b may refer to a remaining area of the substrate 133 except for the first area 130a.

According to an embodiment, the first area 130a may have the first-type pixels 134a arranged therein, and the second area 130b may have the second-type pixels 134b arranged therein. The sensor 160 may receive light through a space between the first-type pixels 134a. The sensor 160 may capture a picture or measure the distance from the external object by receiving the light through the space between the first-type pixels 134a.

According to an embodiment, the brightness of the first area 130a may be substantially similar to the brightness of the second area 130b. For example, the size of the first-type pixels 134a may be larger than the size of the second-type pixels 134b. The size of the first-type pixels 134a is larger than the size of the second-type pixels 134b, so, even if a smaller number of pixels are disposed in the first area 130a, the brightness of the first area 130a may be substantially similar to the brightness of the second area 130b. According to an embodiment of the disclosure, the first area 130a and the second area 130b are visually identically recognized in brightness by a user, so the first area 130a and the second area 130b may not be visually distinguished therebetween.

According to another embodiment of the disclosure, the processor 150 may control the first-type pixels 134a to emit light brighter than light emitted from the second-type pixels 134b. Accordingly, even if a smaller number of pixels are disposed in the first area 130a, the brightness of the first area 130a may be substantially similar to the brightness of the second area 130b. The first area 130a and the second area 130b are substantially similar to each other in brightness, so the user may not visually recognize that the first area 130a is different from the second area 130b (e.g., may visually recognize that the first area 130a is similar to the second area 130b).

In the disclosure, the description made with reference to FIGS. 1 and 2 will be identically applied to the components having the same reference numerals as those of the components of the electronic device 100 illustrated in FIGS. 1 and 2.

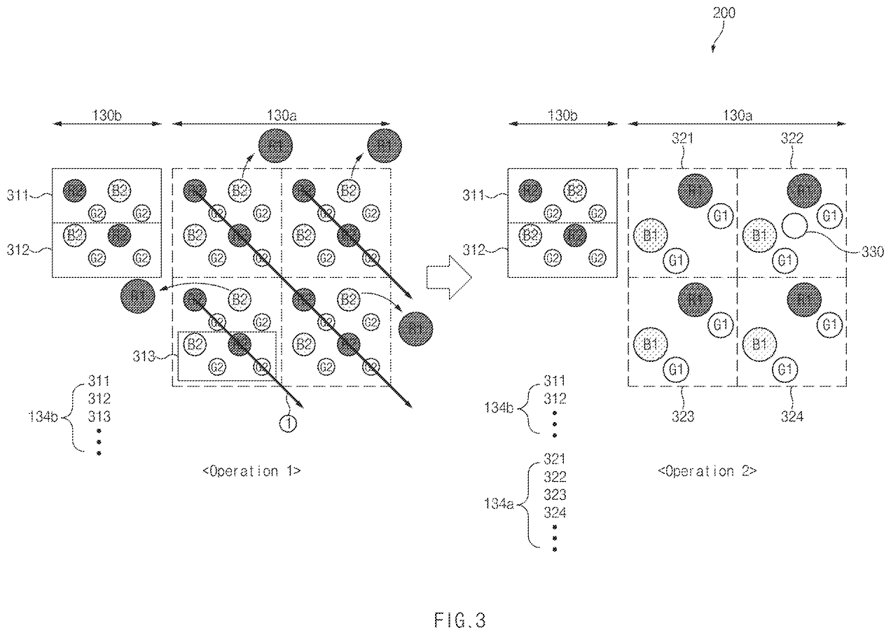

FIG. 3 is an enlarged view illustrating a partial area of the display according to an embodiment of the disclosure. FIG. 3 is a view illustrating the structure of the first-type pixels 134a and the manufacturing process of the first-type pixels 134a, and is an enlarged view of a partial area 200 illustrated in FIG. 2.

Referring to FIG. 3, second-type pixels 311, 312, and 313 may be disposed in the first area 130a and the second area 130b in first operation (Operation 1). Each of the second-type pixels 311, 312, and 313 may include a red subpixel (e.g., R2), a green subpixel (e.g., G2), a blue subpixel (e.g., B2), and a green subpixel (e.g., G2).

In the state that second-type pixels 311, 312, and 313 are arranged in the first area 130a and the second area 130b, subpixels, which are arranged in a first direction \hat{1}, may be removed from the first area 130a. For example, red subpixels (e.g., R2) and green subpixels (e.g., G2) may be removed, and thus, the blue subpixels (e.g., B2) and the green subpixels (e.g., G2) may be present in the first area 130a.

In the state that the red subpixels (e.g., R2) and green subpixels (e.g., G2) are removed, the first-type pixels 321, 322, 323, and 324 may be disposed at the positions of the blue subpixels (e.g., B2) and the green subpixels (e.g., G2). For example, some of blue subpixels (e.g., B2) may be substituted for red subpixels (e.g., R1), and the size of the each of the subpixels may be increased. When the red subpixels (e.g., R2) and the green subpixels (e.g., G2) are removed, only the blue subpixels (e.g., B2) and the green subpixels (e.g., G2) are present, so the color of the first area 130a may be cyan. However, according to an embodiment of the disclosure, some of blue subpixels (e.g., B2) may be substituted for red subpixels (e.g., R1), thereby preventing the color of the first area 130a from being changed to cyan.

The subpixels (e.g., R1, B1, and G1) included in the first-type pixels 321, 322, 323, and 324 may be larger than subpixels (e.g., R2, B2, and G2) included in the second-type pixels 311, 312, and 313 in the second operation (Operation 2). For example, the subpixels (e.g., R1, B1, and G1) included in the first-type pixels 321, 322, 323, and 324 may be at least two times larger than subpixels (e.g., R2, B2, and G2) included in the second-type pixels 311, 312, and 313. The subpixels (e.g., R1, B1, and G1) included in the first-type pixels 321, 322, 323, and 324 are larger than the subpixels (e.g., R2, B2, and G2) included in the second-type pixels 311, 312, and 313. Accordingly, even if a smaller number of subpixels (or pixels) may be disposed in the first area 130a, the brightness of the first area 130a may be substantially similar to the brightness of the second area 130b. The first area 130a and the second area 130b are substantially similar to each other in brightness, so the user may not visually recognize that the first area 130a is different from the second area 130b (e.g., may visually recognize that the first area 130a is similar to the second area 130b).

According to an embodiment, the sensor 160 may receive light through spaces among subpixels (e.g., R1, B1, and G1) included in the first-type pixels 321, 322, 323, and 324. For example, when the sensor 160 is a camera, the camera may capture a picture through a space (e.g., 330) between subpixels. According to another embodiment, when the sensor 160 is the proximity sensor 160, the proximity sensor 160 may measure the distance from the external object through the space 330 between the subpixels.

Although FIG. 3 illustrates that the first area 130a has the rectangle shape for the convenience of explanation, the shape of the first area 130a may correspond to the shape of the sensor 160. For example, when the sensor 160 has a hexagonal shape, even the first area 130a may have the hexagonal shape. Although FIG. 3 illustrates that each subpixel has a circular shape for the convenience of explanation, the shape of the subpixel is not limited to the circular shape.

In the disclosure, each of the subpixels included in the first-type pixels 321, 322, 323, and 324 may be referred to as the first-red-subpixel (e.g., R1), the first-blue-subpixel (e.g., B1), and the first-green-subpixel (e.g., G1). Each of the subpixels included in the second-type pixels 311, 312, and 313 may include a second-red-subpixel (e.g., R2), a second-blue-subpixel (e.g., B2), and a second-green-subpixel (e.g., G2).

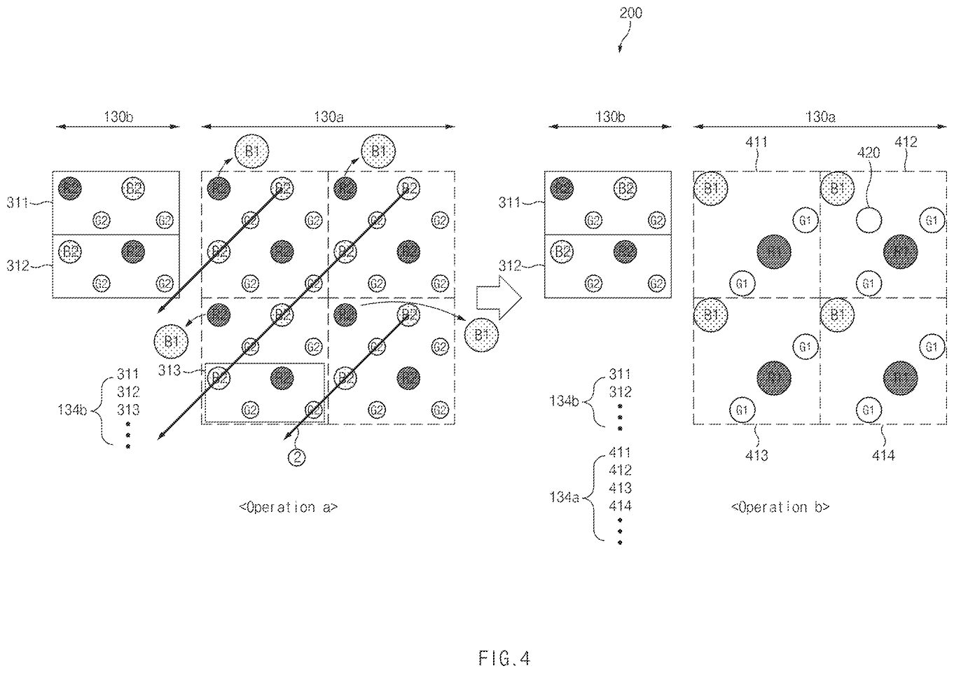

FIG. 4 is an enlarged view illustrating a partial area of the display according to an embodiment of the disclosure. FIG. 4 is a view illustrating the structure of the first-type pixels 134a and the manufacturing process of the first-type pixels 134a according to an embodiment, and is an enlarged view of the partial area 200 illustrated in FIG. 2.

Referring to FIG. 4, the second-type pixels 311, 312, and 313 may be disposed in the first area 130a and the second area 130b in Operation ‘a’. Each of the second-type pixels 311, 312, and 313 may include a red subpixel (e.g., R2), a green subpixel (e.g., G2), a blue subpixel (e.g., B2), and a green subpixel (e.g., G2).

In the state that the second-type pixels 311, 312, and 313 are arranged in the first area 130a and the second area 130b, subpixels, which are arranged in the second direction \hat{2}, may be removed from the first area 130a. For example, the blue subpixels (e.g., B2) and the green subpixels (e.g., G2) may be removed and thus the red subpixels (e.g., R2) and the green subpixels (e.g., G2) may be present in the first area 130a.

In the state that the blue subpixels (e.g., B2) and the green subpixels (e.g., G2) are removed, the first-type pixels 411, 412, 413, and 414 may be disposed at the positions of the red subpixels (e.g., R2) and the green subpixels (e.g., G2). For example, some of red subpixels (e.g., R2) may be substituted for blue subpixels (e.g., B1), and the size of the each of the subpixels may be increased. When the blue subpixels (e.g., B2) and the green subpixels (e.g., G2) are removed, only the red subpixels (e.g., R2) and the green subpixels (e.g., G2) are present, so the color of the first area 130a may be yellowish. However, according to an embodiment of the disclosure, some of red subpixels (e.g., R2) may be substituted for blue subpixels (e.g., B1), thereby preventing the color of the first area 130a from being changed to yellowish.

For example, the subpixels (e.g., R1, B1, and G1) included in the first-type pixels 411, 412, 413, and 414 may be larger than the subpixels (e.g., R2, B2, and G2) included in the second-type pixels 311, 312, and 313 in operation “b”. For example, the subpixels (e.g., R1, B1, and G1) included in the first-type pixels 411, 412, 413, and 414 may be at least two times larger than subpixels (e.g., R2, B2, and G2) included in the second-type pixels 311, 312, and 313. The subpixels (e.g., R1, B1, and G1) included in the first-type pixels 411, 412, 413, and 414 are larger than the subpixels (e.g., R2, B2, and G2) included in the second-type pixels 311, 312, and 313. Accordingly, even if a smaller number of subpixels (or pixels) may be disposed in the first area 130a, the brightness of the first area 130a may be substantially similar to the brightness of the second area 130b. The first area 130a and the second area 130b are substantially similar to each other in brightness, so the user may not visually recognize that the first area 130a is different from the second area 130b (e.g., may visually recognize that the first area 130a is similar to the second area 130b).

According to an embodiment, the sensor 160 may receive light through a space (e.g., 420) among subpixels (e.g., R1, B1, and G1) included in the first-type pixels 411, 412, 413, and 414. For example, when the sensor 160 is a camera, the camera may capture a picture through the spaces (e.g., 420) between subpixels. According to another embodiment, when the sensor 160 is the proximity sensor 160, the proximity sensor 160 may measure the distance from the external object through the space (e.g., 420) among the subpixels.

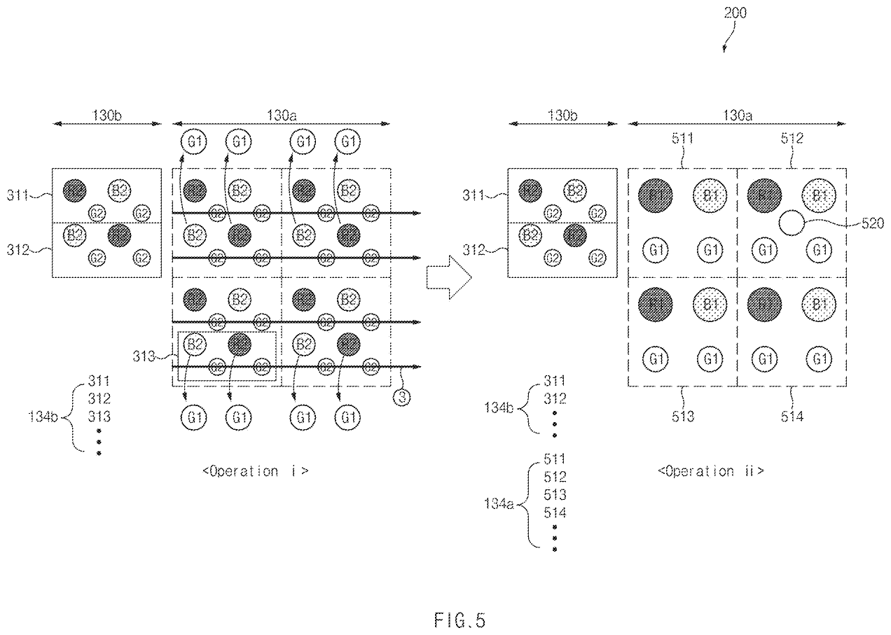

FIG. 5 is an enlarged view illustrating a partial area of the display according to an embodiment of the disclosure. FIG. 5 is a view illustrating the structure of the first-type pixels 134a and the manufacturing process of the first-type pixels 134a according to an embodiment, and is an enlarged view of the partial area 200 illustrated in FIG. 2.

Referring to FIG. 5, the second-type pixels 311, 312, and 313 may be disposed in the first area 130a and the second area 130b in Operation “i”. Each of the second-type pixels 311, 312, and 313 may include a red subpixel (e.g., R2), a green subpixel (e.g., G2), a blue subpixel (e.g., B2), and a green subpixel (e.g., G2).

In the state that the second-type pixels 311, 312, and 313 are arranged in the first area 130a and the second area 130b, subpixels, which are arranged in the third direction \hat{3}, may be removed from the first area 130a. For example, green subpixels (e.g., G2) may be removed, and thus, the red subpixels (e.g., R2) and the blue subpixels (e.g., B2) may be present in the first area 130a.

In the state that the green subpixels (e.g., G2) are removed, first-type pixels 511, 512, 513, and 514 may be disposed at the positions of the red subpixels (e.g., R2) and the blue subpixels (e.g., B2). For example, some of red subpixels (e.g., R2) and blue subpixels (e.g., B2) may be substituted for green subpixels (e.g., G1), and the size of the each of the subpixels may be increased. When the green subpixels (e.g., G2) are removed, only the red subpixels (e.g., R2) and the blue subpixels (e.g., B2) are present, so the color of the first area 130a may be magenta. However, according to an embodiment of the disclosure, some of red subpixels (e.g., R2) and blue subpixels (e.g., B2) may be substituted for green subpixels (e.g., G1), thereby preventing the color of the first area 130a from being changed to magenta.

For example, the subpixels (e.g., R1, B1, and G1) included in the first-type pixels 511, 512, 513, and 514 may be larger than subpixels (e.g., R2, B2, and G2) included in the second-type pixels 311, 312, and 313 in operation “ii”. For example, the subpixels (e.g., R1, B1, and G1) included in the first-type pixels 511, 512, 513, and 514 may be at least two times larger than subpixels (e.g., R2, B2, and G2) included in the second-type pixels 311, 312, and 313. The subpixels (e.g., R1, B1, and G1) included in the first-type pixels 511, 512, 513, and 514 are larger than the subpixels (e.g., R2, B2, and G2) included in the second-type pixels 311, 312, and 313. Accordingly, even if a smaller number of subpixels (or pixels) may be disposed in the first area 130a, the brightness of the first area 130a may be substantially similar to the brightness of the second area 130b. The first area 130a and the second area 130b are substantially similar to each other in brightness, so the user may not visually recognize that the first area 130a is different from the second area 130b (e.g., may visually recognize that the first area 130a is similar to the second area 130b).

According to an embodiment, the sensor 160 may receive light through a space (e.g., 520) among subpixels included in the first-type pixel. For example, when the sensor 160 is a camera, the camera may capture a picture through the space (e.g., 520) among the subpixels. According to another embodiment, when the sensor 160 is the proximity sensor 160, the proximity sensor 160 may measure the distance from the external object through the space (e.g., 530) among the subpixels.

According to an embodiment, the size of remaining subpixels may be increased in proportion to the number of removed subpixels. For example, as the number of removed subpixels is increased, the size of the remaining subpixels may be increased more. Referring to FIG. 5, the second-type pixels 311, 312, and 313 may be disposed in the first area 130a and the second area 130b in Operation “i”. Each of the second-type pixels 311, 312, and 313 may include a red subpixel (e.g., R2), a green subpixel (e.g., G2), a blue subpixel (e.g., B2), and a green subpixel (e.g., G2).

In the state that the second-type pixels 311, 312, and 313 are arranged in the first area 130a and the second area 130b, subpixels (e.g., G2), which are arranged in the third direction \hat{3}, may be removed from the first area 130a. The red subpixel (e.g., R2) and the blue subpixel (e.g., B2) may be disposed in the first area 130a by increasing the sizes of the red subpixel (e.g., R2) and the blue subpixel (e.g., B2) as the number of the subpixels (e.g., G2) removed in the third direction is increased. When the size of the remaining subpixels is increased in proportion to the number of the removed subpixels, the user may not visually recognize that the first area 130a is different from the second area 130b (e.g., may visually recognize that the first area 130a is similar to the second area 130b) because the first area 130a and the second area 130b are substantially similar to each other in brightness.

According to an embodiment of the disclosure, an electronic device may include a housing, a display at least partially disposed inside the housing, and, a sensor. The display may include a display panel, first-type pixels disposed on a first area, which corresponds to the sensor, of the display panel, and second-type pixels disposed on a second area of the display panel other than the first area. Each of the first-type pixels may include a first-red-subpixel, a first-blue-subpixel, and a first-green-subpixel, and each of the second-type pixels may include a second-red-subpixel smaller than the first-red-subpixel, a second-blue-subpixel smaller than the first-blue-subpixel, and a second-green-subpixel smaller than the first-green subpixel. A first arrangement in which the first-red-subpixel, the first-blue-subpixel, and the first-green-subpixel are arranged may be different from a second arrangement in which the second-red-subpixel, the second-blue-subpixel, and the second-green-subpixel are arranged.

According to an embodiment of the disclosure, the first-red-subpixel, the first-blue-subpixel, and the first-green-subpixel may be arranged in mutually different lines.

According to an embodiment of the disclosure, a line in which the first-red-subpixel and the first-blue-subpixel are arranged may be different from a line in which the first-green-subpixel is arranged.

According to an embodiment of the disclosure, a line in which the second-red-subpixel and the second-blue-subpixel are arranged may be different from a line in which the second-green-subpixel is arranged.

According to an embodiment of the disclosure, the number of the first-type pixels arranged per unit area may be different from the number of the second-type pixels arranged per unit area.

According to an embodiment of the disclosure, each of the first-type pixels may further include a first-green-subpixel, and each of the second-type pixels may further include a second-green-subpixel.

According to an embodiment of the disclosure, the first-red-subpixel may have a size which is specified times larger than a size of the second-red-subpixel, the first-blue-subpixel may have a size which is specified times larger than a size of the second-blue-subpixel, and the first-green-subpixel may have a size which is specified times larger than a size of the second-green-subpixel.

According to an embodiment of the disclosure, the electronic device may further include a printed circuit board interposed between the display and the housing, and a processor disposed on the printed circuit board.

According to an embodiment of the disclosure, the processor may control the first-type pixels to emit light brighter than light emitted from the second-type pixels.

According to an embodiment of the disclosure, an opening may be formed in a specified area of the first area, and the sensor may receive light through the opening.

According to an embodiment of the disclosure, the sensor may include a camera, and the sensor may obtain an image based on the light.

According to an embodiment of the disclosure, the sensor may include a proximity sensor, and the sensor may obtain a distance between an external object and the electronic device based on the light.

According to an embodiment of the disclosure, the sensor may include an illumination sensor, and the sensor may obtain an external illuminance of the electronic device based on the light.

According to an embodiment of the disclosure, a display may include a display panel, first-type pixels disposed on a first area, which corresponds to an external sensor, of the display panel, and second-type pixels disposed on a second area of the display panel other than the first area. Each of the first-type pixels may include a first-red-subpixel, a first-blue-subpixel, and a first-green-subpixel, each of the second-type pixels may include a second-red-subpixel smaller than the first-red-subpixel, a second-blue-subpixel smaller than the first-blue-subpixel, and a second-green-subpixel smaller than the first-green subpixel, and a first arrangement in which the first-red-subpixel, the first-blue-subpixel, and the first-green-subpixel are arranged may be different from a second arrangement in which the second-red-subpixel, the second-blue-subpixel, and the second-green-subpixel are arranged.

According to an embodiment of the disclosure, the first-red-subpixel, the first-blue-subpixel, and the first-green-subpixel may be arranged in mutually different lines.

According to an embodiment of the disclosure, a line in which the first-red-subpixel and the first-blue-subpixel are arranged may be different from a line in which the first-green-subpixel is arranged.

According to an embodiment of the disclosure, a line in which the second-red-subpixel and the second-blue-subpixel are arranged may be different from a line in which the second-green-subpixel is arranged.

According to an embodiment of the disclosure, the number of the first-type pixels arranged per unit area may be different from the number of the second-type pixels arranged per unit area.

According to an embodiment of the disclosure, each of the first-type pixels further may include a first-green-subpixel, and each of the second-type pixels may further include a second-green-subpixel.

According to an embodiment of the disclosure, the first-red-subpixel may have a size which is specified times larger than a size of the second-red-subpixel, the first-blue-subpixel may have a size which is specified times larger than a size of the second-blue-subpixel, and the first-green-subpixel may have a size which is specified times larger than a size of the second-green-subpixel.

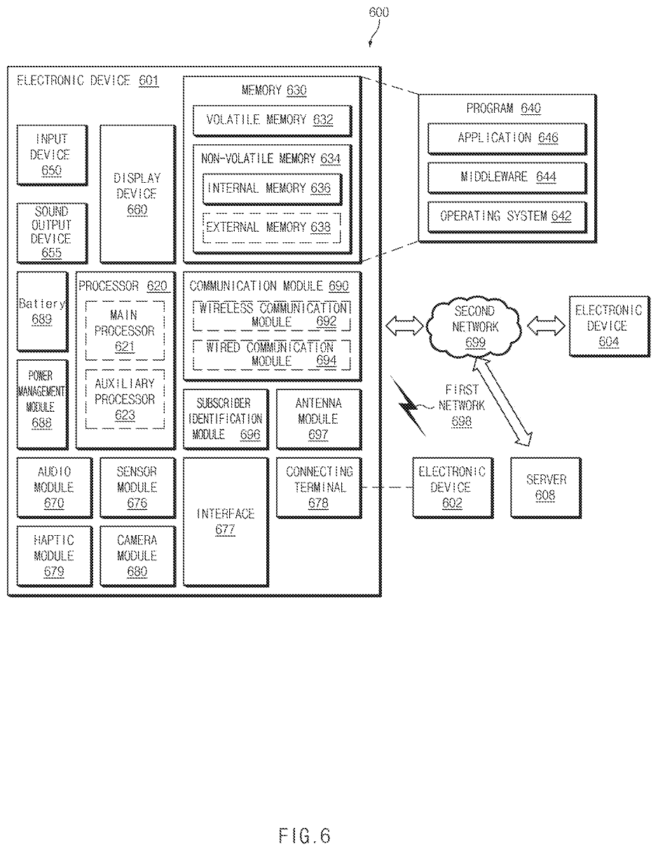

FIG. 6 is a block diagram illustrating an electronic device in a network environment according to an embodiment of the disclosure.

Referring to FIG. 6, an electronic device 601 in a network environment 600 may communicate with an electronic device 602 via a first network 698 (e.g., a short-range wireless communication network), or an electronic device 604 or a server 608 via a second network 699 (e.g., a long-range wireless communication network). According to an embodiment, the electronic device 601 may communicate with the electronic device 604 via the server 608. According to an embodiment, the electronic device 601 may include a processor 620, memory 630, an input device 650, a sound output device 655, a display device 660, an audio module 670, a sensor module 676, an interface 677, a haptic module 679, a camera module 680, a power management module 688, a battery 689, a communication module 690, a subscriber identification module (SIM) 696, or an antenna module 697. In some embodiments, at least one (e.g., the display device 660 or the camera module 680) of the components may be omitted from the electronic device 601, or one or more other components may be added in the electronic device 601. In some embodiments, some of the components may be implemented as single integrated circuitry. For example, the sensor module 676 (e.g., a fingerprint sensor, an iris sensor, or an illuminance sensor) may be implemented as embedded in the display device 660 (e.g., a display).

The processor 620 may execute, for example, software (e.g., a program 640) to control at least one other component (e.g., a hardware or software component) of the electronic device 601 coupled with the processor 620, and may perform various data processing or computation. According to one embodiment, as at least part of the data processing or computation, the processor 620 may load a command or data received from another component (e.g., the sensor module 676 or the communication module 690) in volatile memory 632, process the command or the data stored in the volatile memory 632, and store resulting data in non-volatile memory 634. According to an embodiment, the processor 620 may include a main processor 621 (e.g., a central processing unit (CPU) or an application processor (AP)), and an auxiliary processor 623 (e.g., a graphics processing unit (GPU), an image signal processor (ISP), a sensor hub processor, or a communication processor (CP)) that is operable independently from, or in conjunction with, the main processor 621. Additionally or alternatively, the auxiliary processor 623 may be adapted to consume less power than the main processor 621, or to be specific to a specified function. The auxiliary processor 623 may be implemented as separate from, or as part of the main processor 621.

The auxiliary processor 623 may control at least some of functions or states related to at least one component (e.g., the display device 660, the sensor module 676, or the communication module 690) among the components of the electronic device 601, instead of the main processor 621 while the main processor 621 is in an inactive (e.g., sleep) state, or together with the main processor 621 while the main processor 621 is in an active state (e.g., executing an application). According to an embodiment, the auxiliary processor 623 (e.g., an image signal processor or a communication processor) may be implemented as part of another component (e.g., the camera module 680 or the communication module 690) functionally related to the auxiliary processor 623.

The memory 630 may store various data used by at least one component (e.g., the processor 620 or the sensor module 676) of the electronic device 601. The various data may include, for example, software (e.g., the program 640) and input data or output data for a command related thereto. The memory 630 may include the volatile memory 632 or the non-volatile memory 634.

The program 640 may be stored in the memory 630 as software, and may include, for example, an operating system (OS) 642, middleware 644, or an application 646.

The input device 650 may receive a command or data to be used by other component (e.g., the processor 620) of the electronic device 601, from the outside (e.g., a user) of the electronic device 601. The input device 650 may include, for example, a microphone, a mouse, a keyboard, or a digital pen (e.g., a stylus pen).

The sound output device 655 may output sound signals to the outside of the electronic device 601. The sound output device 655 may include, for example, a speaker or a receiver. The speaker may be used for general purposes, such as playing multimedia or playing record, and the receiver may be used for an incoming calls. According to an embodiment, the receiver may be implemented as separate from, or as part of the speaker.

The display device 660 may visually provide information to the outside (e.g., a user) of the electronic device 601. The display device 660 may include, for example, a display, a hologram device, or a projector and control circuitry to control a corresponding one of the display, hologram device, and projector. According to an embodiment, the display device 660 may include touch circuitry adapted to detect a touch, or sensor circuitry (e.g., a pressure sensor) adapted to measure the intensity of force incurred by the touch.

The audio module 670 may convert a sound into an electrical signal and vice versa. According to an embodiment, the audio module 670 may obtain the sound via the input device 650, or output the sound via the sound output device 655 or a headphone of an external electronic device (e.g., an electronic device 602) directly (e.g., wiredly) or wirelessly coupled with the electronic device 601.

The sensor module 676 may detect an operational state (e.g., power or temperature) of the electronic device 601 or an environmental state (e.g., a state of a user) external to the electronic device 601, and then generate an electrical signal or data value corresponding to the detected state. According to an embodiment, the sensor module 676 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 677 may support one or more specified protocols to be used for the electronic device 601 to be coupled with the external electronic device (e.g., the electronic device 602) directly (e.g., wiredly) or wirelessly. According to an embodiment, the interface 677 may include, for example, a high definition multimedia interface (HDMI), a universal serial bus (USB) interface, a secure digital (SD) card interface, or an audio interface.

A connecting terminal 678 may include a connector via which the electronic device 601 may be physically connected with the external electronic device (e.g., the electronic device 602). According to an embodiment, the connecting terminal 678 may include, for example, a HDMI connector, a USB connector, a SD card connector, or an audio connector (e.g., a headphone connector).

The haptic module 679 may convert an electrical signal into a mechanical stimulus (e.g., a vibration or a movement) or electrical stimulus which may be recognized by a user via his tactile sensation or kinesthetic sensation. According to an embodiment, the haptic module 679 may include, for example, a motor, a piezoelectric element, or an electric stimulator.

The camera module 680 may capture a still image or moving images. According to an embodiment, the camera module 680 may include one or more lenses, image sensors, image signal processors, or flashes.

The power management module 688 may manage power supplied to the electronic device 601. According to one embodiment, the power management module 688 may be implemented as at least part of, for example, a power management integrated circuit (PMIC).

The battery 689 may supply power to at least one component of the electronic device 601. According to an embodiment, the battery 689 may include, for example, a primary cell which is not rechargeable, a secondary cell which is rechargeable, or a fuel cell.

The communication module 690 may support establishing a direct (e.g., wired) communication channel or a wireless communication channel between the electronic device 601 and the external electronic device (e.g., the electronic device 602, the electronic device 604, or the server 608) and performing communication via the established communication channel. The communication module 690 may include one or more communication processors that are operable independently from the processor 620 (e.g., the application processor (AP)) and supports a direct (e.g., wired) communication or a wireless communication. According to an embodiment, the communication module 690 may include a wireless communication module 692 (e.g., a cellular communication module, a short-range wireless communication module, or a global navigation satellite system (GNSS) communication module) or a wired communication module 694 (e.g., a local area network (LAN) communication module or a power line communication (PLC) module). A corresponding one of these communication modules may communicate with the external electronic device via the first network 698 (e.g., a short-range communication network, such as Bluetooth™, Wi-Fi direct, or infrared data association (IrDA)) or the second network 699 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 692 may identify and authenticate the electronic device 601 in a communication network, such as the first network 698 or the second network 699, using subscriber information (e.g., international mobile subscriber identity (IMSI)) stored in the subscriber identification module 696.

The antenna module 697 may transmit or receive a signal or power to or from the outside (e.g., the external electronic device) of the electronic device 601. According to an embodiment, the antenna module 697 may include an antenna including a radiating element composed of a conductive material or a conductive pattern formed in or on a substrate (e.g., PCB). According to an embodiment, the antenna module 697 may include a plurality of antennas. In such a case, at least one antenna appropriate for a communication scheme used in the communication network, such as the first network 698 or the second network 699, may be selected, for example, by the communication module 690 (e.g., the wireless communication module 692) from the plurality of antennas. The signal or the power may then be transmitted or received between the communication module 690 and the external electronic device via the selected at least one antenna. According to an embodiment, another component (e.g., a radio frequency integrated circuit (RFIC)) other than the radiating element may be additionally formed as part of the antenna module 697.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 601 and the external electronic device 604 via the server 608 coupled with the second network 699. Each of the electronic devices 602 and 604 may be a device of a same type as, or a different type, from the electronic device 601. According to an embodiment, all or some of operations to be executed at the electronic device 601 may be executed at one or more of the external electronic devices 602, 604, or 608. For example, if the electronic device 601 should perform a function or a service automatically, or in response to a request from a user or another device, the electronic device 601, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 601. The electronic device 601 may provide the outcome, with or without further processing of the outcome, as at least part of a reply to the request. To that end, a cloud computing, distributed computing, or client-server computing technology may be used, for example.

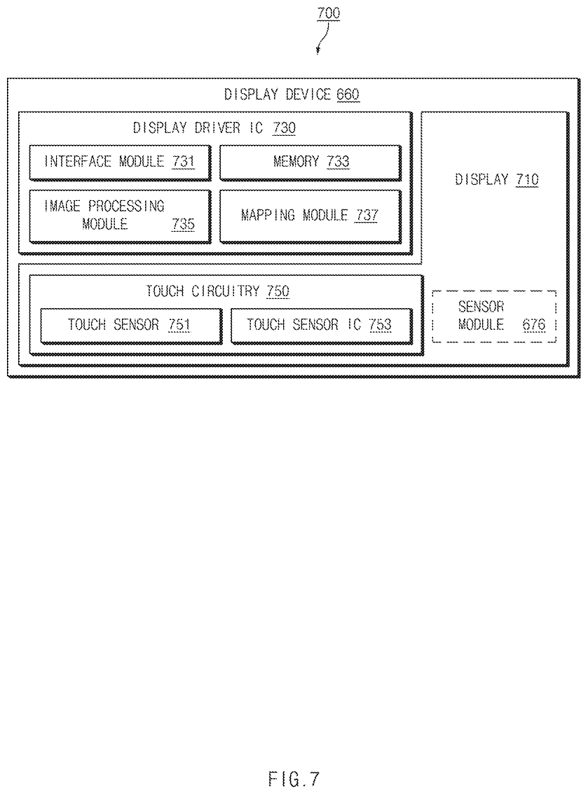

FIG. 7 is a block diagram illustrating the display device according to an embodiment of the disclosure.

Referring to FIG. 7, in a block diagram 700 a display device 660 may include a display 710 and a display driver integrated circuit (DDI) 730 to control the display 710. The DDI 730 may include an interface module 731, memory 733 (e.g., buffer memory), an image processing module 735, or a mapping module 737. The DDI 730 may receive image information that contains image data or an image control signal corresponding to a command to control the image data from another component of the electronic device 601 via the interface module 731. For example, according to an embodiment, the image information may be received from the processor 620 (e.g., the main processor 621 (e.g., an application processor)) or the auxiliary processor 623 (e.g., a graphics processing unit) operated independently from the function of the main processor 621. The DDI 730 may communicate, for example, with touch circuitry (i.e., input device 650) or the sensor module 676 via the interface module 731. The DDI 730 may also store at least part of the received image information in the memory 733, for example, on a frame by frame basis.

The image processing module 735 may perform pre-processing or post-processing (e.g., adjustment of resolution, brightness, or size) with respect to at least part of the image data. According to an embodiment, the pre-processing or post-processing may be performed, for example, based at least in part on one or more characteristics of the image data or one or more characteristics of the display 710.

The mapping module 737 may generate a voltage value or a current value corresponding to the image data pre-processed or post-processed by the image processing module 735. According to an embodiment, the generating of the voltage value or current value may be performed, for example, based at least in part on one or more attributes of the pixels (e.g., an array, such as an RGB stripe or a pentile structure, of the pixels, or the size of each subpixel). At least some pixels of the display 710 may be driven, for example, based at least in part on the voltage value or the current value such that visual information (e.g., a text, an image, or an icon) corresponding to the image data may be displayed via the display 710.

According to an embodiment, the display device 660 may further include touch circuitry 750. The touch circuitry 750 may include a touch sensor 751 and a touch sensor IC 753 to control the touch sensor 751. The touch sensor IC 753 may control the touch sensor 751 to sense a touch input or a hovering input with respect to a certain position on the display 710. To achieve this, for example, the touch sensor 751 may detect (e.g., measure) a change in a signal (e.g., a voltage, a quantity of light, a resistance, or a quantity of one or more electric charges) corresponding to the certain position on the display 710. The touch circuitry 750 may provide input information (e.g., a position, an area, a pressure, or a time) indicative of the touch input or the hovering input detected via the touch sensor 751 to the processor 620. According to an embodiment, at least part (e.g., the touch sensor IC 753) of the touch circuitry 750 may be formed as part of the display 710 or the DDI 730, or as part of another component (e.g., the auxiliary processor 623) disposed outside the display device 660.

According to an embodiment, the display device 660 may further include at least one sensor (e.g., a fingerprint sensor, an iris sensor, a pressure sensor, or an illuminance sensor) of the sensor module 676 or a control circuit for the at least one sensor. In such a case, the at least one sensor or the control circuit for the at least one sensor may be embedded in one portion of a component (e.g., the display 710, the DDI 730, or the touch circuitry (i.e., input device 650)) of the display device 660. For example, when the sensor module 676 embedded in the display device 660 includes a biometric sensor (e.g., a fingerprint sensor), the biometric sensor may obtain biometric information (e.g., a fingerprint image) corresponding to a touch input received via a portion of the display 710. As another example, when the sensor module 676 embedded in the display device 660 includes a pressure sensor, the pressure sensor may obtain pressure information corresponding to a touch input received via a partial or whole area of the display 710. According to an embodiment, the touch sensor 751 or the sensor module 676 may be disposed between pixels in a pixel layer of the display 710, or over or under the pixel layer.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 640) including one or more instructions that are stored in a storage medium (e.g., internal memory 636 or external memory 638) that is readable by a machine (e.g., the electronic device 601). For example, a processor (e.g., the processor 620) of the machine (e.g., the electronic device 601) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

As described above, according to embodiments in the disclosure, the phenomenon that a partial area of the display is visually recognized may be improved.

Besides, a variety of effects directly or indirectly understood through the disclosure may be provided.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device comprising:
a housing;
a display at least partially disposed inside the housing; and
a sensor,
wherein the display comprises:
a display panel,
first-type pixels disposed on a first area, which corresponds to the sensor, of the display pane, and
second-type pixels disposed on a second area of the display panel, the second areas being different from the first area,
wherein each of the first-type pixels comprises a first-red-subpixel, a first-blue-subpixel, and a first-green-subpixel,
wherein each of the second-type pixels comprises a second-red-subpixel smaller than the first-red-subpixel, a second-blue-subpixel smaller than the first-blue-subpixel, and a second-green-subpixel smaller than the first-green subpixel, and
wherein a first arrangement in which the first-red-subpixel, the first-blue-subpixel, and the first-green-subpixel are arranged is different from a second arrangement in which the second-red-subpixel, the second-blue-subpixel, and the second-green-subpixel are arranged.

2. The electronic device of claim 1, wherein the first-red-subpixel, the first-blue-subpixel, and the first-green-subpixel are arranged in mutually different lines.

3. The electronic device of claim 1, wherein a line in which the first-red-subpixel and the first-blue-subpixel are arranged is different from a line in which the first-green-subpixel is arranged.

4. The electronic device of claim 1, wherein a line in which the second-red-subpixel and the second-blue-subpixel are arranged is different from a line in which the second-green-subpixel is arranged.

5. The electronic device of claim 1, wherein a number of the first-type pixels arranged per unit area is different from a number of the second-type pixels arranged per unit area.

6. The electronic device of claim 1,
wherein each of the first-type pixels further comprises the first-green-subpixel, and
wherein each of the second-type pixels further comprises the second-green-subpixel.

7. The electronic device of claim 1,
wherein a size of the first-red-subpixel is specified times larger than a size of the second-red-subpixel,
wherein a size of the first-blue-subpixel is specified times larger than a size of the second-blue-subpixel, and
wherein a size of the first-green-subpixel is specified times larger than a size of the second-green-subpixel.

8. The electronic device of claim 1, further comprising:
a printed circuit board interposed between the display and the housing; and
a processor disposed on the printed circuit board.

9. The electronic device of claim 8, wherein the processor is configured to control the first-type pixels to emit light brighter than light emitted from the second-type pixels.

10. The electronic device of claim 1,
wherein an opening is formed in a specified area of the first area, and
wherein the sensor receives light through the opening.

11. The electronic device of claim 10,
wherein the sensor comprises:
a camera, and
wherein the sensor obtains an image based on the light.

12. The electronic device of claim 10,
wherein the sensor comprises:
a proximity sensor, and
wherein the sensor obtains a distance between an external object and the electronic device based on the light.

13. The electronic device of claim 10,
wherein the sensor comprises an illumination sensor, and
wherein the sensor obtains an external illuminance of the electronic device based on the light.

14. A display comprising:
a display panel;
first-type pixels disposed on a first area, which corresponds to an external sensor, of the display panel; and
second-type pixels disposed on a second area of the display panel, the second area being different from the first area,
wherein each of the first-type pixels comprises a first-red-subpixel, a first-blue-subpixel, and a first-green-subpixel,
wherein each of the second-type pixels comprises a second-red-subpixel smaller than the first-red-subpixel, a second-blue-subpixel smaller than the first-blue-subpixel, and a second-green-subpixel smaller than the first-green subpixel, and
wherein a first arrangement in which the first-red-subpixel, the first-blue-subpixel, and the first-green-subpixel are arranged is different from a second arrangement in which the second-red-subpixel, the second-blue-subpixel, and the second-green-subpixel are arranged.

15. The display of claim 14, wherein the first-red-subpixel, the first-blue-subpixel, and the first-green-subpixel are arranged in mutually different lines.

16. The display of claim 14, wherein a line in which the first-red-subpixel and the first-blue-subpixel are arranged is different from a line in which the first-green-subpixel is arranged.

17. The display of claim 14, wherein a line in which the second-red-subpixel and the second-blue-subpixel are arranged is different from a line in which the second-green-subpixel is arranged.

18. The display of claim 14, wherein a number of the first-type pixels arranged per unit area is different from a number of the second-type pixels arranged per unit area.

19. The display of claim 14,
wherein each of the first-type pixels further comprises the first-green-subpixel, and
wherein each of the second-type pixels further comprises the second-green-subpixel.

20. The display of claim 14,
wherein a size of the first-red-subpixel is specified times larger than a size of the second-red-subpixel,
wherein a size of the first-blue-subpixel is specified times larger than a size of the second-blue-subpixel, and
wherein a size of the first-green-subpixel is specified times larger than a size of the second-green-subpixel.
